(19) United States
(12) Patent Application Publication
(10) Pub. No.: US 2011/0115078 A1
(43) Pub. Date: May 19, 2011

(54) FLIP CHIP PACKAGE

(75) Inventors: Se-Young JEONG, Suwon-si (KR); Nam-Seog Kim, Yongin-si (KR)

(73) Assignee: Samsung Electronics Co., Ltd., Suwon-si (KR)

(21) Appl. No.: 12/906,348

(22) Filed: Oct. 18, 2010

(30) Foreign Application Priority Data
Nov. 13, 2009 (KR) 2009-109587

(51) Int. Cl. H01L 23/48

(52) U.S. Cl. 257/737; 257/778; 257/E23.021

(57) ABSTRACT

A flip chip package may include a semiconductor chip, a package substrate, a conductive magnetic bump and an anisotropic conductive member. The semiconductor chip may have a first pad. The package substrate may have a second pad confronting the first pad. The conductive magnetic bump may be interposed between the semiconductor chip and the package substrate to generate a magnetic force. The anisotropic conductive member may be arranged between the semiconductor chip and the package substrate. The anisotropic conductive member may have conductive magnetic particles induced toward the conductive magnetic bump by the magnetic force to electrically connect the first pad with the second pad. A predetermined number of the conductive magnetic particles may be positioned between the conductive magnetic bump and the pad, so that an electrical connection reliability between the pads may be increased.

### CROSS-REFERENCE TO RELATED APPLICATIONS

This application claims priority under 35 USC §119 to Korean Patent Application No. 2009-109587, filed on Nov. 13, 2009 in the Korean Intellectual Property Office (KIPO), the contents of which are herein incorporated by reference in their entirety.

### BACKGROUND

1. Field of the Invention

Example embodiments of the present general inventive concept relate to a flip chip package and a method of manufacturing the same. More particularly, example embodiments of the present general inventive concept relate to a flip chip package including a conductive bump electrically connected between a package substrate and a semiconductor substrate, and a method of manufacturing the flip chip package.

2. Description of the Related Art

Generally, a plurality of semiconductor fabrication processes may be performed on a semiconductor substrate to form a plurality of semiconductor chips. In order to mount the semiconductor chips on a printed circuit board (PCB), a packaging process may be performed on the semiconductor chips to form semiconductor packages.

The semiconductor package may include a semiconductor chip, a package substrate, and an electrical connecting member. The electrical connecting member may include a conductive wire, a conductive bump, etc.

A semiconductor package including the conductive bump that may be electrically connected between the package substrate and the semiconductor chip may be referred to as a flip chip package. Further, any one of the flip chip packages may include conductive particles between the conductive bump and package substrate to electrically connect the conductive bumps with each other.

An electrical connecting member including the conductive particles may include anisotropic conductive adhesive. The anisotropic conductive adhesive may include anisotropic conductive film, anisotropic conductive paste, etc. The conductive particles may be arranged between the conductive bump and a pad of the package substrate to electrically connect the bump with the pad. Thus, numbers of the conductive particles between the conductive bump and the pad may determine electrical connection reliability between the semiconductor chip and the package substrate.

When the pad may have a wide width, a sufficient number of the conductive particles may be positioned between the pad and the bump. However, when the pad may have a narrow width, an insufficient number of the conductive particles may be positioned between the pad and the bump. This may cause an electrical cut-off between the bump and the pad.

### SUMMARY

Example embodiments of the present general inventive concept provide a flip chip package that may have increased and/or improved electrical connection reliability between a semiconductor chip and a package substrate by arranging a predetermined and/or sufficient number of conductive particles between a narrow pad and a conductive bump.

Example embodiments of the present general inventive concept may also provide a method of manufacturing the above-mentioned flip chip package.

Additional features and utilities of the present general inventive concept will be set forth in part in the description which follows and, in part, will be obvious from the description, or may be learned by practice of the present general inventive concept.

Example embodiments of the present general inventive concept also provide a flip chip package. The flip chip package may include a semiconductor chip, a package substrate, a conductive magnetic bump, and an anisotropic conductive member. The semiconductor chip may have a first pad. The package substrate may have a second pad confronting the first pad. The conductive magnetic bump may be interposed between the semiconductor chip and the package substrate to generate a magnetic force. The anisotropic conductive member may be arranged between the semiconductor chip and the package substrate. The anisotropic conductive member may have conductive magnetic particles induced toward the conductive magnetic bump by the magnetic force to electrically connect the first pad with the second pad.

In example embodiments of the present general inventive concept, the conductive magnetic bump may be arranged on the first pad or the second pad.

In example embodiments of the present general inventive concept, the conductive magnetic bump may include a first bump on the first pad, and a second bump on the second pad.

In example embodiments of the present general inventive concept, the flip chip package may further include external terminals mounted on the package substrate.

Example embodiments of the present general inventive concept also provide a method of manufacturing a flip chip package. In the method of manufacturing the flip chip package, a package substrate having a second pad may be placed over a semiconductor chip having a first pad. A conductive magnetic bump to generate a magnetic force may be formed between the semiconductor chip and the package substrate. An anisotropic conductive member may be arranged between the semiconductor chip and the package substrate. The anisotropic conductive member may have conductive magnetic particles induced toward the conductive magnetic bump by the magnetic force to electrically connect the first pad with the second pad.

In example embodiments of the present general inventive concept, the conductive magnetic bump may be arranged on the first pad or the second pad.

In example embodiments of the present general inventive concept, forming the conductive magnetic bump may include forming a first bump on the first pad, and forming a second bump on the second pad.

In example embodiments of the present general inventive concept, the method may further include mounting external terminals on the package substrate.

According to example embodiments of the present general inventive concept, the conductive magnetic particles may be induced to the conductive magnetic bump by the magnetic force generated from the conductive magnetic bump. Thus, a predetermined and/or sufficient number of the conductive magnetic particles may be positioned between the conductive magnetic bump and the pad, so that electrical connection reliability between the pads may be increased and/or improved.

Exemplary embodiments of the present general inventive concept can also provide a flip chip package including an anisotropic conductive member arranged between a semiconductor chip and a package substrate, the anisotropic conductive member having conductive magnetic particles that are induced by magnetic force toward at least one of a first conductive magnetic bump disposed on a first pad of the semiconductor chip and a second conductive magnetic bump disposed on a second pad of the package substrate to electrically connect the first pad and the second pad with each other, where a surface of the first pad faces a surface of the second pad.

The anisotropic conductive member of the flip chip package can include a predetermined number of conductive magnetic particles.

The conductive magnetic particles of the flip chip package can include a circular polymer core, a nickel layer formed on an outer surface of the polymer core, a gold layer formed on an outer surface of the nickel layer, and a polymer layer formed on an outer surface of the gold layer.

The flip chip package can include where the conductive magnetic particles has at least one of a cobalt layer, a molybdenum layer, and an iron layer.

Exemplary embodiments of the present general inventive concept may also provide a method of manufacturing a flip chip package, the method including forming an anisotropic conductive member between a semiconductor chip and a package substrate, forming a first conductive magnetic bump on a first pad of the semiconductor chip, and forming a second conductive magnetic bump on a second pad of the package substrate, where the anisotropic conductive member includes conductive magnetic particles that are induced by magnetic force of at least one of the first magnetic bump and the second magnetic bump to electrically connect the first pad and the second pad with each other.

The forming of the anisotropic conductive member in the method may include disposing a predetermined number of conductive magnetic particles in the anisotropic conductive member.

The conductive magnetic particles may include a circular polymer core, a nickel layer formed on an outer surface of the polymer core, a gold layer formed on an outer surface of the nickel layer, and a polymer layer formed on an outer surface of the gold layer.

The method may include where the conductive magnetic particles have at least one of cobalt layer, a molybdenum layer, and an iron layer.

### BRIEF DESCRIPTION OF THE DRAWINGS

The above and/or other aspects of the present general inventive concept will become apparent and more readily appreciated from the following description of the exemplary embodiments, taken in conjunction with the accompanying drawings, in which:

FIG. 1 is a cross-sectional view illustrating a flip chip package in accordance with example embodiments of the present general inventive concept;

FIG. 2 is an enlarge cross-sectional view illustrating conductive magnetic particles in an anisotropic conductive member of the flip chip package in FIG. 1 according to exemplary embodiments of the present general inventive concept;

FIGS. 3 and 4 are cross-sectional views illustrating a method of manufacturing the flip chip package in FIG. 1 according to exemplary embodiments of the present general inventive concept;

FIG. 5 is a cross-sectional view illustrating a flip chip package in accordance with example embodiments of the present general inventive concept;

FIGS. 6 and 7 are cross-sectional views illustrating a method of manufacturing the flip chip package in FIG. 5 according to exemplary embodiments of the present general inventive concept;

FIG. 8 is a cross-sectional view illustrating a flip chip package in accordance with example embodiments of the present general inventive concept; and

FIGS. 9 to 11 are cross-sectional views illustrating a method of manufacturing the flip chip package in FIG. 8 according to exemplary embodiments of the present general inventive concept.

### DETAILED DESCRIPTION OF THE EMBODIMENTS

Example embodiments of the present general inventive concept will be described more fully hereinafter with reference to the accompanying drawings, in which several example embodiments are illustrated. The present general inventive concept may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity. The embodiments are described below in order to explain the present general inventive concept by referring to the figures.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present general inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present general inventive concept are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments of the present general inventive concept should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments of the present general inventive concept will be explained in detail with reference to the accompanying drawings.

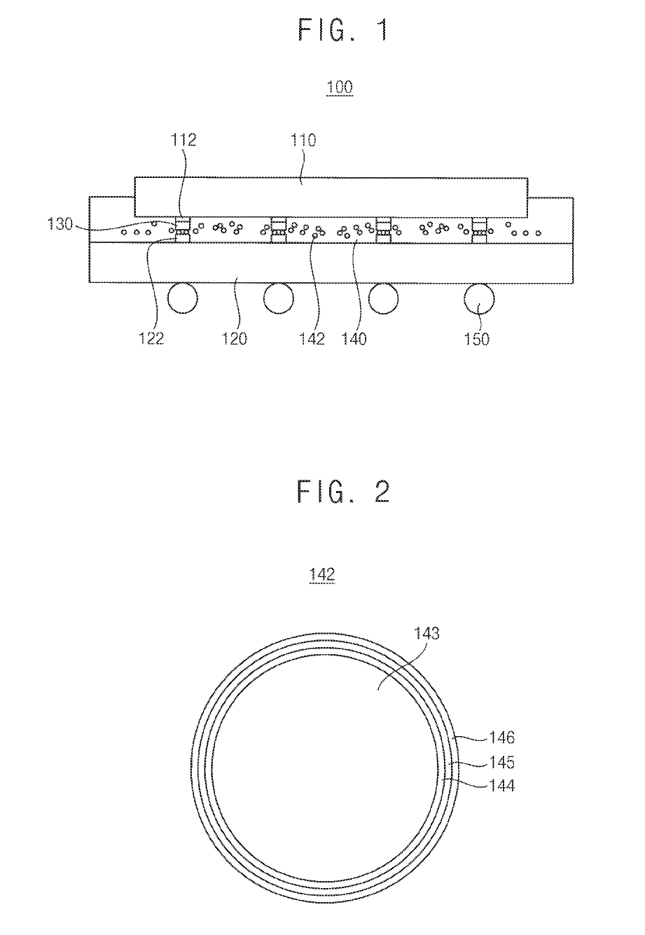

FIG. 1 is a cross-sectional view illustrating a flip chip package in accordance with example embodiments of the present general inventive concept, and FIG. 2 is an enlarge cross-sectional view illustrating conductive magnetic particles in an anisotropic conductive member of the flip chip package in FIG. 1.

Referring to FIG. 1, a flip chip package 100 of example embodiments of the present general inventive concept may include a semiconductor chip, a package substrate 120, a conductive magnetic bump 130, an anisotropic conductive member 140, and external terminals 150.

The semiconductor chip 110 may have a plurality of first pads 112. In example embodiments of the present general inventive concept, the first pads 112 may be arranged on a lower surface of the semiconductor chip 110.

The package substrate 120 may be placed under the semiconductor chip 110. The package substrate 120 may have a plurality of second pads 122. In example embodiments of the present general inventive concept, the second pads 112 may be arranged on an upper surface of the package substrate 120. Thus, the second pads 122 may face the first pads 112. That is, a surface of the first pads 112 may face a surface of the second pads 122.

The conductive magnetic bump 130 may be arranged between the first pads 112 and the second pads 122. In example embodiments of the present general inventive concept, the conductive magnetic bump 130 may make contact with the first pad 112. Thus, the conductive magnetic bump 130 may be electrically connected to the first pad 112. The conductive magnetic bump 130 may be spaced apart from the second pad 122. Thus, the conductive magnetic bump 130 may be electrically isolated from the second pad 122.

In example embodiments of the present general inventive concept, the conductive magnetic bump 130 may generate a magnetic force. The magnetic force may be applied to a space between the conductive magnetic bump 130 and the second pad 122. It is possible that the magnetic force may be applied to a space adjacent to the space between the conductive magnetic bump 130 and second pads 122 and/or a space around the conductive magnetic bump 130 and the second pads 122. The conductive magnetic bump 130 may be formed by an electroplating process or an electroless plating process using a magnetic material such as nickel, cobalt, molybdenum, iron, etc. The conductive magnetic bump 130 may have ferromagnetism such as a permanent magnet. The magnetic force generated form the conductive magnetic bump 130 may be controlled by a preferred orientation control. That is, the magnetic force generated by the conductive magnetic bump 130 may be controlled by its placement with respect to the second pad 122.

The anisotropic conductive member 140 may fill a space between the semiconductor chip 110 and the package substrate 120. In example embodiments of the present general inventive concept, the anisotropic conductive member 140 may include an insulating material and a plurality of conductive magnetic particles 142 placed in the insulating material. The anisotropic conductive member 140 may include an anisotropic conductive adhesive, an anisotropic conductive paste, etc.

In example embodiments of the present general inventive concept, the conductive magnetic particles 142 in the anisotropic conductive member 140 may have magnetism. As illustrated in FIG. 2, the conductive magnetic particles 142 may include a circular polymer core 143, a nickel layer 144 plated and/or formed on an outer surface of the polymer core 143, a gold layer 145 plated and/or formed on an outer surface of the nickel layer 144, and a polymer layer 146 formed on an outer surface of the gold layer 145. The nickel layer 144 may be formed by an electroplating process, an electroless plating process, or any other suitable process to carry out the exemplary embodiments of the present general inventive concept disclosed herein so to have magnetism, so that the conductive magnetic particles 142 may have the magnetism. Alternatively, the conductive magnetic particles 142 may include a cobalt layer, a molybdenum layer, an iron layer, etc.

In example embodiments of the present general inventive concept, the magnetic force generated from the conductive magnetic bump 130 may be applied to the conductive magnetic particles 142 disposed in at least one of the above spaces. The conductive magnetic particles 142 may be induced toward the conductive magnetic bump 130. Thus, a predetermined and/or sufficient number of the conductive magnetic particles 142 may be distributed in the space between the conductive magnetic bump 130 and the second pad 122. Particularly, a predetermined and/or sufficient number of the conductive magnetic particles 142 may be arranged between the narrow first pad 112 and the narrow second pad 122. The conductive magnetic bump 130 and the second pad 122 may be electrically connected with each other via a predetermined and/or sufficient number of the conductive magnetic particles 142, so that electrical connection reliability between the semiconductor chip 110 and the package substrate 120 may be increased and/or improved. That is, a predetermined number of the conductive magnetic particles 142 can be arranged between the first pad 112 and the second pad 122 so as to increase the electrical connection between the semiconductor chip 110 and the package substrate 120. A gap between the conductive magnetic bump 130 and package substrate 120 may have a distance so as to be filled with at least some of the conductive magnetic particles 142. The distance may be shorter than a width along a surface of the conductive magnetic bump 130 or the package substrate 122. The distance may be longer than a diameter of at least one of the conductive magnetic particles 142.

The external terminals 150 may be mounted on a lower surface of the package substrate 120. The external terminals 150 may be electrically connected to the second pads 122. In example embodiments of the present general inventive concept, the external terminals 150 may include solder balls.

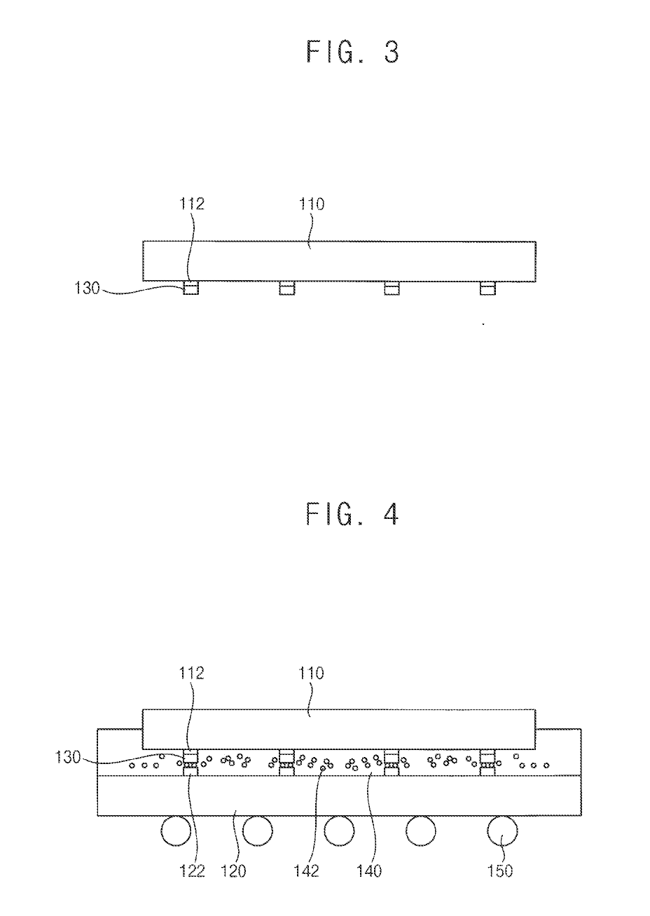

FIGS. 3 and 4 are cross-sectional views illustrating a method of manufacturing the flip chip package in FIG. 1 according to exemplary embodiments of the present general inventive concept.

Referring to FIG. 3, the conductive magnetic bump 130 may be formed on the first pad 112 of the semiconductor chip 110. In example embodiments of the present general inventive concept, the conductive magnetic bump 130 may be formed by an electroplating process or an electroless plating process using a magnetic material such as nickel, cobalt, molybdenum, iron, etc.

Referring to FIG. 4, the semiconductor chip 110 may be placed over the package substrate 120. In example embodiments of the present general inventive concept, the conductive magnetic bump 130 and the first pad 112 may be oriented toward the package substrate 120. The space between the semiconductor chip 110 and the package substrate 120 may be filled with the anisotropic conductive member 140. In example embodiments of the present general inventive concept, the anisotropic conductive member 140 may include an anisotropic conductive adhesive, an anisotropic conductive paste, etc., including the conductive magnetic particles 142. That is, in exemplary embodiments of the present general inventive concept, the space between the semiconductor chip 110 and the package substrate 120 may be filled with the anisotropic conductive member 140 that can include a predetermined number of conductive magnetic particles 142. The predetermined number of conductive magnetic particles 142 can increase the electrical connection between the semiconductor chip 110 and the package substrate 120.

The external terminals 150 such as the solder balls may be mounted on the package substrate 120 of the flip chip package 100.

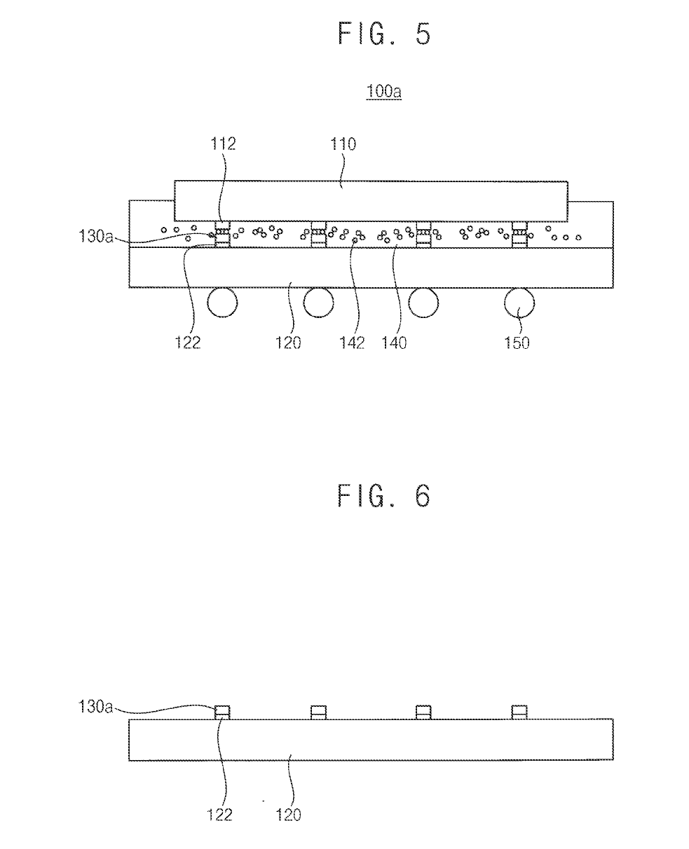

FIG. 5 is a cross-sectional view illustrating a flip chip package in accordance with example embodiments of the present general inventive concept.

Here, a flip chip package 100a of example embodiments of the present general inventive concept may include elements substantially the same as those of the flip chip package 100 illustrated in FIG. 1 and described except for a conductive magnetic bump 130a. Thus, the same reference numerals refer to the same elements and any further illustrations with respect to the same elements are omitted herein for brevity.

Referring to FIG. 5, the flip chip package 100a of example embodiments of the present general inventive concept may include a conductive magnetic bump 130a on the second pad 122 of the package substrate 120. The conductive magnetic bump 130a may not be arranged on the first pad 112 of the semiconductor chip 110.

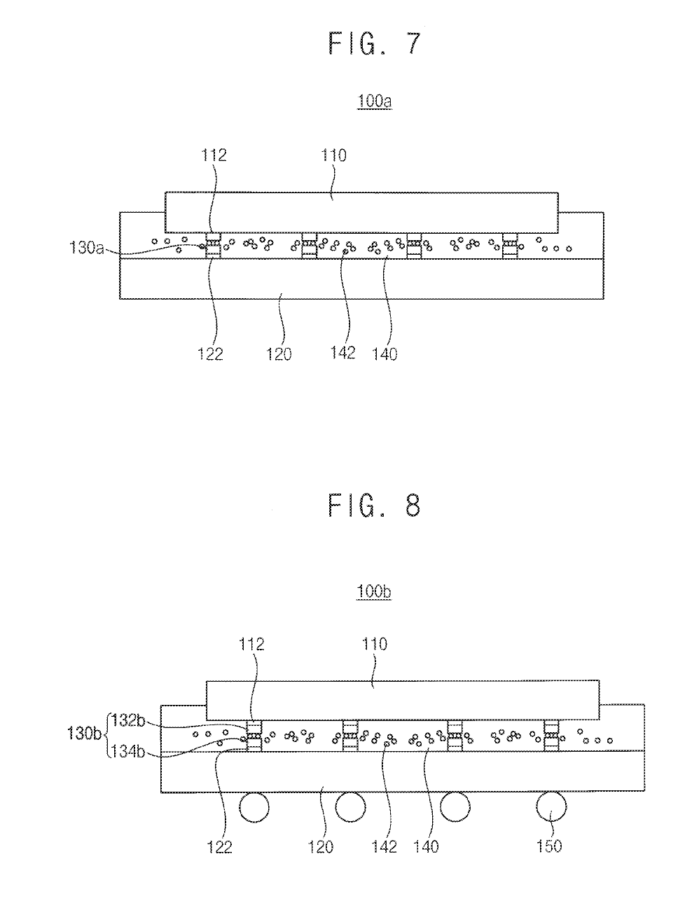

FIGS. 6 and 7 are cross-sectional views illustrating a method of manufacturing the flip chip package in FIG. 5 according to exemplary embodiments of the present general inventive concept.

Referring to FIG. 6, the conductive magnetic bump 130a may be formed on the second pad 122 of the package substrate 120.

Referring to FIG. 7, the semiconductor chip 110 of the flip chip package 110a being formed may be arranged over the package substrate 120. In example embodiments of the present general inventive concept, the first pad 112 may be oriented toward the conductive magnetic bump 130a. The space between the semiconductor chip 110 and the package substrate 120 may be filled with the anisotropic conductive member 140. In exemplary embodiments of the present general inventive concept, the anisotropic conductive member 140 may include a predetermined number of conductive magnetic particles 142 so as to increase the electrical connection between the semiconductor chip 110 and the package substrate 120.

The external terminals 150, such as the solder balls, may be mounted on the package substrate 120 to complete the flip chip package 100a in FIG. 5.

FIG. 8 is a cross-sectional view illustrating a flip chip package 100b in accordance with example embodiments of the present general inventive concept.

Here, a flip chip package 100b of the example embodiments of the present general inventive concept may include elements substantially the same as those of the flip chip package 100 illustrated in FIG. 1 and described above, except for a conductive magnetic bump 130b. Thus, the same reference numerals refer to the same elements and any further illustrations with respect to the same elements are omitted herein for brevity.

Referring to FIG. 8, the flip chip package 100b of example embodiments of the present general inventive concept may include a conductive magnetic bump 130b. The conductive magnetic bump 130b may include a first bump 132b on the first pad 112 of the semiconductor chip 110, and a second bump 134b on the second pad 122 of the package substrate 120. Thus, a magnetic force generated from the first bump 132b and the second bump 134b can stronger than that generated from the conductive magnetic bump 130 or 130a may be applied to the conductive magnetic particles 142 in the anisotropic conductive member 140.

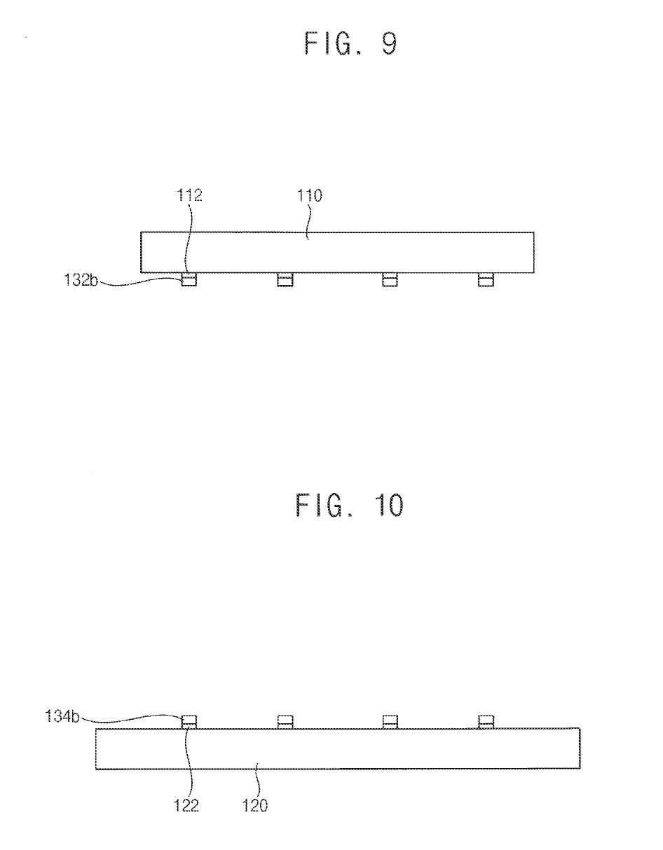

FIGS. 9 to 11 are cross-sectional views illustrating a method of manufacturing the flip chip package illustrated in FIG. 8 according to exemplary embodiments of the present general inventive concept.

Referring to FIG. 9, the first bump 132b may be formed on the first pad 112 of the semiconductor chip 110.

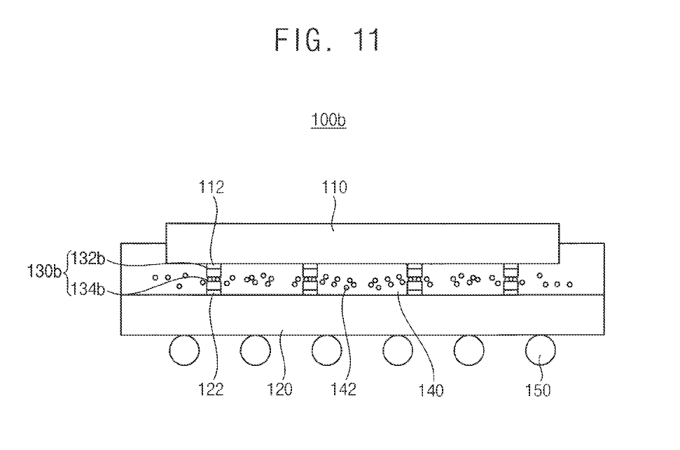

Referring to FIG. 10, the second bump 134b may be formed on the second pad 122 of the package substrate 120.

Referring to FIG. 11, the semiconductor chip 110 may be arranged over the package substrate 120. In example embodiments, the first pad 112 may face the second pad 122. That is, a surface of the first pad 112 may face a surface of the second pad 122. The space between the semiconductor chip 110 and the package substrate 120 may be filled with the anisotropic conductive member 140. In exemplary embodiments of the present general inventive concept, the anisotropic conductive member 140 may include a predetermined number of conductive magnetic particles 142 so as to increase the electrical connection between the semiconductor chip 110 and the package substrate 120.

The external terminals 150 such as the solder balls may be mounted on the package substrate 120 to complete the flip chip package 100b in FIG. 8.

According to example embodiments of the present general inventive concept, the conductive magnetic particles may be induced to the conductive magnetic bump by the magnetic force generated from the conductive magnetic bump. Thus, a predetermined and/or sufficient number of the conductive magnetic particles may be positioned between the conductive magnetic bump and the pad, so that electrical connection reliability between the pads may be increased and/or improved.

The foregoing is illustrative of example embodiments and is not to be construed as limiting thereof. Although several example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of example embodiments of the present general inventive concept and is not to be construed as limited to the specific example embodiments disclosed, and that modifications to the disclosed example embodiments, as well as other example embodiments, are intended to be included within the scope of the appended claims.

1. A flip chip package comprising:
a semiconductor chip having a first pad;
a package substrate having a second pad that faces the first pad;
a conductive magnetic bump interposed between the semiconductor chip and the package substrate to generate a magnetic force; and
an anisotropic conductive member arranged between the semiconductor chip and the package substrate, the anisotropic conductive member having conductive magnetic particles that are induced toward the conductive magnetic bump by the magnetic force to electrically connect the first pad and the second pad with each other.

2. The flip chip package of claim 1, wherein the conductive magnetic bump is arranged on the first pad.

3. The flip chip package of claim 1, wherein the conductive magnetic bump is arranged on the second pad.

4. The flip chip package of claim 1, wherein the conductive magnetic bump comprises:
a first bump arranged on the first pad; and
a second bump arranged on the second pad.

5. The flip chip package of claim 1, wherein the conductive magnetic bump comprises nickel, cobalt, molybdenum or iron.

6. The flip chip package of claim 1, wherein the conductive magnetic particles comprise nickel, cobalt, molybdenum or iron.

7. The flip chip package of claim 1, wherein the anisotropic conductive member comprises an anisotropic conductive adhesive or an anisotropic conductive paste.

8. The flip chip package of claim 1, further comprising external terminals mounted on the package substrate.

9-14. (canceled)

15. A flip chip package comprising:
an anisotropic conductive member arranged between a semiconductor chip and a package substrate, the anisotropic conductive member having conductive magnetic particles that are induced by magnetic force toward at least one of a first conductive magnetic bump disposed on a first pad of the semiconductor chip and a second conductive magnetic bump disposed on a second pad of the package substrate to electrically connect the first pad and the second pad with each other,
wherein a surface of the first pad faces a surface of the second pad.

16. The flip chip package of claim 15, wherein the anisotropic conductive member includes a predetermined number of conductive magnetic particles.

17. The flip chip package of claim 16, wherein the conductive magnetic particles comprise:
a circular polymer core;
a nickel layer formed on an outer surface of the polymer core;
a gold layer formed on an outer surface of the nickel layer; and
a polymer layer formed on an outer surface of the gold layer.

18. The flip chip package of claim 16, wherein the conductive magnetic particles comprise at least one of a cobalt layer, a molybdenum layer, and an iron layer.

19-20. (canceled)
